(19) United States
(12) Patent Application Publication
(10) Pub. No.: US 2023/0098317 A1
(43) Pub. Date: Mar. 30, 2023

(54) DISPLAY DEVICE

(71) Applicant: Samsung Display Co., LTD., Yongin-si (KR)

(72) Inventor: Sang Hyo PARK, Suwon-si (KR)

(73) Assignee: Samsung Display Co., LTD., Yongin-si (KR)

(21) Appl. No.: 17/825,529

(22) Filed: May 26, 2022

(30) Foreign Application Priority Data
Sep. 27, 2021 (KR) 10-2021-0127281

(51) Int. Cl. G06F 1/16

(52) U.S. Cl. CPC G06F 1/1652; G06F 1/1624

(57) ABSTRACT

A display device includes a display layer including a first region including a display area, a second region spaced apart from the first region in a first direction, and a third region located between the first region and the second region, the third region being bent. The display device further includes a first lower film disposed on a bottom surface of the display layer and overlapping the first region in a plan view, a second lower film disposed on the bottom surface of the display layer, overlapping the second region in a plan view, and spaced apart from the first lower film, a first adhesive member disposed between the display layer and the first lower film and having a first thickness, and a second adhesive member disposed between the display layer and the second lower film and having a second thickness smaller than the first thickness.

### CROSS-REFERENCE TO RELATED APPLICATION(S)

This application claims priority to and benefits of Korean Patent Application No. 10-2021-0127281 under 35 U.S.C. 119, filed on Sep. 27, 2021 in the Korean Intellectual Property Office (KIPO), the entire contents of which are herein incorporated by reference.

### BACKGROUND

### 1. Technical Field

The disclosure relates to a display device.

### 2. Description of the Related Art

The importance of display devices has steadily increased with the development of multimedia technology. Accordingly, various types of display devices such as liquid crystal display (LCD) devices, organic light emitting display (OLED) devices, and the like have been used.

In recent years, with the development of display technology, research and development has been actively conducted on a display device having a flexible display. A flexible display may be capable of extending or reducing the display screen by folding, bending, or sliding the display screen, thereby contributing great1y to a volume reduction or a design change of the display device.

In order to support the bottom portion of a flexible display of a sliding device, there may be a multi joint structure made of a metal material under the display. However, stress occurring in a folding area by a sliding operation may be applied to a display panel, which may cause a defect.

### SUMMARY

Aspects of the disclosure provide a display device capable of minimizing a display defect caused by application of stress, which may occur by a sliding operation, to a display panel.

However, aspects of the disclosure are not restricted to the above. The above and other aspects of the disclosure will become more apparent to one of ordinary skill in the art to which the disclosure pertains by referencing the detailed description of the disclosure given below.

A display device according to an embodiment may reduce stress applied to the display panel by changing physical properties and a thickness of an adhesive member, which may be disposed in the display panel, for each area, thereby decreasing display device defects.

However, the effects of the disclosure are not limited to the aforementioned effects, and various other effects are included in the specification.

According to an embodiment of the disclosure, a display device may include a display layer including a first region including a display area, a second region spaced apart from the first region in a first direction, and a third region between the first region and the second region, the third region being bent. The display device may further include a first lower film disposed on a bottom surface of the display layer and overlapping the first region in a plan view, a second lower film disposed on the bottom surface of the display layer, overlapping the second region in a plan view, and spaced apart from the first lower film, a first adhesive member disposed between the display layer and the first lower film and having a first thickness, and a second adhesive member disposed between the display layer and the second lower film and having a second thickness smaller than the first thickness.

In an embodiment, a storage modulus of the first adhesive member may be smaller than a storage modulus of the second adhesive member.

In an embodiment, the first adhesive member and the second adhesive member may include a same material.

In an embodiment, the first lower film and the second lower film may include a same material.

In an embodiment, the display layer may further include an auxiliary region extending from a first side of the first region in a second direction intersecting the first direction, the display device may further include a roller surrounded by at least a part of the auxiliary region, and a position of a bending portion of the auxiliary region may be moved in the second direction by movement of the roller. In a first state, the auxiliary region may overlap the first region in a plan view, and in a second state, the auxiliary region may not overlap the first region in a plan view.

In an embodiment, the display device may further include a support member disposed on the bottom surface of the display layer. The support member may include a joint portion overlapping the auxiliary region in a plan view, and a flat plate portion overlapping the first region in a plan view.

In an embodiment, the first region may overlap the second adhesive member in a plan view.

In an embodiment, the display device may further include a printed circuit board disposed on a top surface of the display layer and overlapping the second region in a plan view, wherein the printed circuit board may partially overlap the second adhesive member in a plan view.

According to another embodiment of the disclosure, a display device may include a display layer including a first region including a display area, a second region spaced apart from the first region in a first direction, and a third region between the first region and the second region, the third region being bent. The display device may further include a first lower film disposed on a bottom surface of the display layer and overlapping the first region in a plan view, a second lower film disposed on the bottom surface of the display layer, overlapping the second region in a plan view, and spaced apart from the first lower film, a first adhesive member disposed between the display layer and the first lower film, and a second adhesive member disposed between the display layer and the second lower film. The second adhesive member may include a base film, a first sub-adhesive layer disposed between the base film and the second region, and a second sub-adhesive layer disposed between the base film and the second lower film.

In an embodiment, the first adhesive member may have a first thickness, and the first thickness may be greater than a thickness of the first sub-adhesive layer and may be greater than a thickness of the second sub-adhesive layer.

In an embodiment, the first thickness may be greater than a sum of a thickness of the first sub-adhesive layer and a thickness of the second sub-adhesive layer.

In an embodiment, a storage modulus of the first adhesive member may be smaller than at least one of a storage modulus of the first sub-adhesive layer and a storage modulus of the second sub-adhesive layer.

In an embodiment, the storage modulus of the first sub-adhesive layer and the storage modulus of the second sub-adhesive layer may be equal to each other.

In an embodiment, the first adhesive member, the first sub-adhesive layer, and the second sub-adhesive layer may include a same material.

In an embodiment, the first adhesive member may have a first thickness, and the second adhesive member may have a second thickness equal to the first thickness.

In an embodiment, the first lower film and the second lower film may include a same material.

In an embodiment, the display layer may further include an auxiliary region extending from a first side of the first region in a second direction intersecting the first direction, the display device may further include a roller surrounded by at least a part of the auxiliary region, a position of a bending portion of the auxiliary region may be moved in the second direction by movement of the roller, in a first state, the auxiliary region may overlap the first region in a plan view, and in a second state, the auxiliary region may not overlap the first region in a plan view.

In an embodiment, the display device may further include a support member disposed on the bottom surface of the display layer, wherein the support member may include a joint portion overlapping the auxiliary region in a plan view, and a flat plate portion overlapping the first region in a plan view.

In an embodiment, the first region may overlap the second adhesive member in a plan view.

In an embodiment, the display device may further include a printed circuit board disposed on a top surface of the display layer and overlapping the second region in a plan view, wherein the printed circuit board may partially overlap the second adhesive member in a plan view.

### BRIEF DESCRIPTION OF THE DRAWINGS

The above and other aspects and features of the disclosure will become more apparent by describing in detail embodiments thereof with reference to the attached drawings, in which:

FIGS. 1A and 1B are schematic perspective views illustrating a display device according to an embodiment;

FIGS. 2A and 2B are schematic cross-sectional views of a display device according to an embodiment;

FIG. 3 is a schematic cross-sectional view of a pixel of a display device according to an embodiment;

FIG. 4 is an enlarged schematic view of region Q of FIG. 2B;

FIGS. 5 to 11 are schematic views illustrating a manufacturing process of a display device according to an embodiment;

FIG. 12 is a schematic diagram illustrating a part of a display device according to another embodiment;

FIG. 13 is an enlarged schematic view of region P of FIG. 12; and

FIGS. 14 to 19 are schematic diagrams illustrating a manufacturing process of a display device according to another embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when a layer is referred to as being “on” another layer or substrate, it can be direct1y on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

For the convenience of description, in referring to the display device or the surfaces of each member constituting the display device, a surface facing the direction in which an image may be displayed may be referred to as the upper surface, and another surface, which may be opposite of the display surface, may be referred to as a lower surface. However, the disclosure is not limited thereto, and the display surface and another surface of the member may be referred to as a front surface and a rear surface, respectively, or may be referred to as a first surface or a second surface.

The terms “overlap” or “overlapped” mean that a first object may be above or below or to a side of a second object, and vice versa. Additionally, the term “overlap” may include layer, stack, face or facing, extending over, covering, or part1y covering or any other suitable term as would be appreciated and understood by those of ordinary skill in the art.

The terms “face” and “facing” mean that a first element may direct1y or indirect1y oppose a second element. In a case in which a third element intervenes between the first and second element, the first and second element may be understood as being indirect1y opposed to one another, although still facing each other.

When an element is described as “not overlapping” or to “not overlap” another element, this may include that the elements are spaced apart from each other, offset from each other, or set aside from each other or any other suitable term as would be appreciated and understood by those of ordinary skill in the art.

“About”, “approximately”, “substantially”, and the like, as used herein, are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

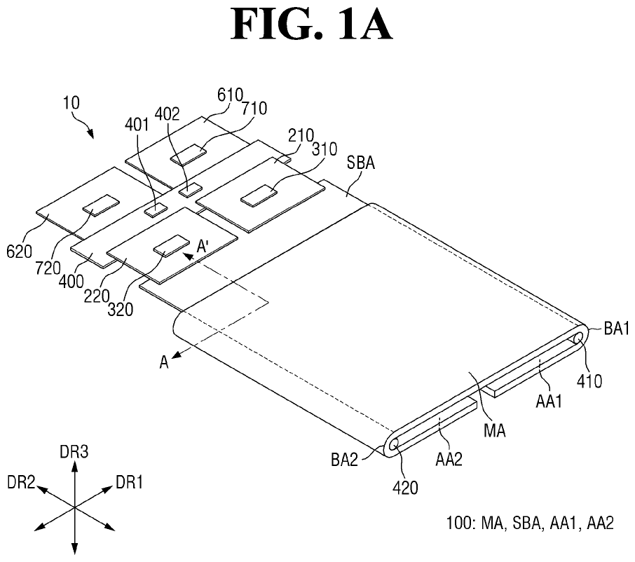

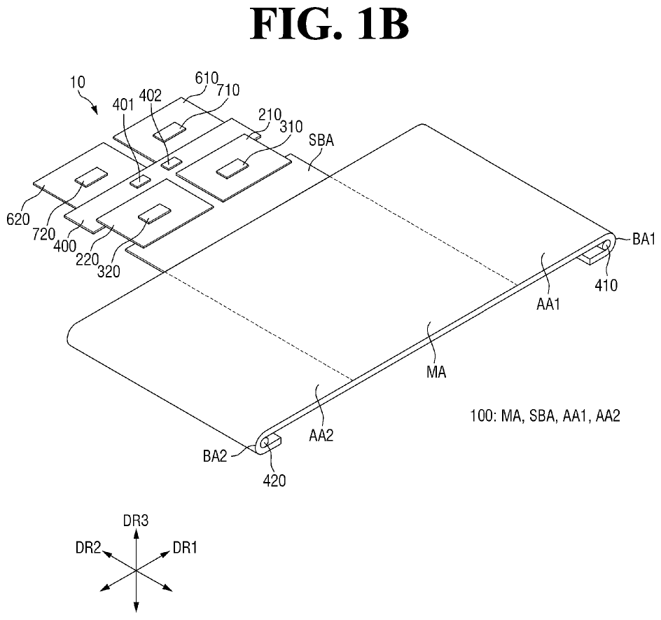

FIGS. 1A and 1B are schematic perspective views illustrating a display device according to an embodiment. FIG. 1A is a perspective view illustrating a first state of a display device 10, and FIG. 1B is a perspective view illustrating a second state of the display device 10.

Referring to FIGS. 1A and 1B, the display device 10 may be applied to portable electronic devices such as a mobile phone, a smartphone, a tablet personal computer, a mobile communication terminal, an electronic organizer, an electronic book, a portable multimedia player (P1VIP), a navigation system, an ultra mobile PC (UMPC) or the like. In other embodiments, the display device 10 may be applied to a display unit of a television, a laptop, a monitor, a billboard, or an Internet-of-Things (IoT) device. In other embodiments, the display device 10 may be applied to wearable devices such as a smart watch, a watch phone, a glasses type display, or a head mounted display (HMD).

Further, the display device 10 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 10 is an organic light emitting display device, but the disclosure is not limited thereto.

The display device 10 may include a display panel 100, a first source circuit board 210, a second source circuit board 220, a first source driving circuit 310, a second source driving circuit 320, a control circuit board 400, a timing control circuit 401, a first circuit board 610, a second circuit board 620, a first integrated circuit 710, and a second integrated circuit 720.

The display panel 100 may be a flexible display panel that may be bent or curved by a first roller 410 and a second roller 420. The display panel 100 may include a main region MA, a pad-region SBA, a first auxiliary region AA1, and a second auxiliary region AA2.

In FIGS. 1A and 1B, a first direction DR1 may indicate a horizontal direction of the display panel 100, a second direction DR2 may indicate a vertical direction of the display panel 100, and a third direction DR3 may indicate a thickness direction of the display panel 100. “Left”, “right”, “upper” and “lower” may indicate directions when the display panel 100 is viewed from above. For example, “right side” may indicate a side of the first direction DR1, “left side” may indicate another side of the first direction DR1, “upper side” may indicate a side of the second direction DR2, and “lower side” may indicate another side of the second direction DR2. Further, “above” may indicate a side in the third direction DR3, and “below” may indicate another side in the third direction DR3.

The main region MA may be a flat area that may not be bent or curved, but is not limited thereto. The main region MA may have a rectangular shape in plan view, but is not limited thereto. The length of the main region MA in the first direction DR1 may be longer than the length thereof in the second direction DR2.

The pad-region SBA may be disposed on a side of the main region MA in the second direction DR2. For example, the pad-region SBA may extend from the main region MA in the second direction DR2.

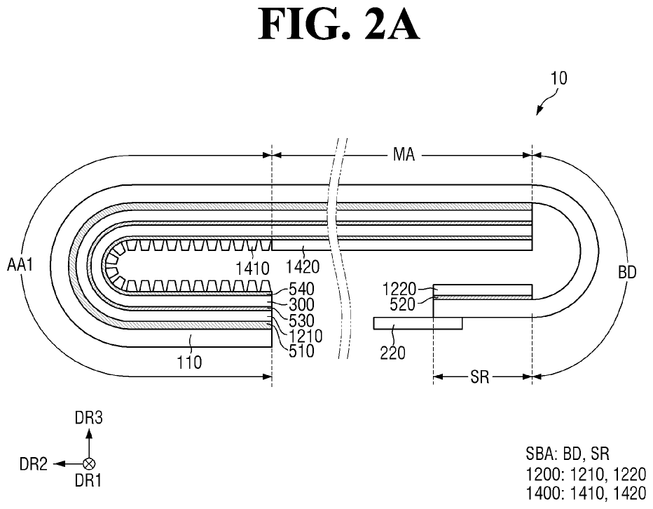

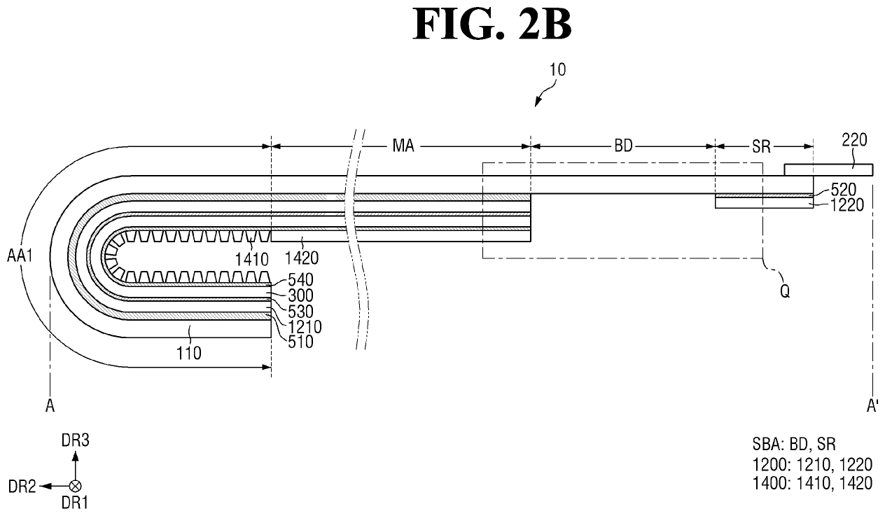

The pad-region SBA may be a region to be bent or curved. The pad-region SBA may be bent with a curvature. Therefore, the pad-region SBA may include a bendable bending region BD (see, e.g., FIG. 2A) and a pad region SR (see, e.g., FIG. 2A) in which pads may be disposed. In case that the pad-region SBA is bent, the pad region SR of the pad-region SBA may overlap the main region MA in the third direction DR3. The pad-region SBA may have a rectangular shape in plan view, but is not limited thereto.

The length of the pad-region SBA in the first direction DR1 may be substantially the same as the length of the main region MA in the first direction DR1. In other embodiments, the length of the pad-region SBA in the first direction DR1 may be less than the length of the main region MA in the first direction DR1. The length of the pad-region SBA in the second direction DR2 may be less than the length of the main region MA in the second direction DR2.

The first auxiliary region AA1 may be disposed on a side of the main region MA in the first direction DR1. For example, the first auxiliary region AA1 may extend from a side of the main region MA in the first direction DR1.

The second auxiliary region AA2 may be disposed on another side of the main region MA in the first direction DR1. For example, the second auxiliary region AA2 may extend from another side of the main region MA in the first direction DR1.

The first auxiliary region AA1 and the second auxiliary region AA2 may be regions to be curved or bent. The first auxiliary region AA1 may be bent or curved along the first roller 410. The second auxiliary region AA2 may be bent or curved along the second roller 420. Each of the first auxiliary region AA1 and the second auxiliary region AA2 may be bent with a curvature.

Each of the lengths of the first auxiliary region AA1 and the second auxiliary region AA2 in the first direction DR1 may be less than the length of the main region MA in the first direction DR1. Each of the lengths of the first auxiliary region AA1 and the second auxiliary region AA2 in the second direction DR2 may be substantially the same as the length of the main region MA in the second direction DR2.

The first source circuit board 210 and the second source circuit board 220 may be attached to a side edge of the pad-region SBA. The side of the pad-region SBA may be opposite to another side of the pad-region SBA, which may be in contact with the main region MA.

Each of the first source circuit board 210 and the second source circuit board 220 may be attached onto pads disposed on a side edge of the pad-region SBA using an anisotropic conductive film (ACF). Accordingly, each of the first source circuit board 210 and the second source circuit board 220 may be electrically connected to a pad portion of the display panel 100. The first source circuit board 210 and the second source circuit board 220 may be a flexible film, such as a flexible printed circuit board, a printed circuit board, or a chip on film.

The first source driving circuit 310 and the second source driving circuit 320 may output data voltages to data lines of the display panel 100. For example, the first source driving circuit 310 may be connected to the data lines of the display panel 100 via the first source circuit board 210 and the pads of the pad-region SBA. Further, the second source driving circuit 320 may be connected to the data lines of the display panel 100 via the second source circuit board 220 and the pads of the pad-region SBA.

Each of the first source driving circuit 310 and the second source driving circuit 320 may be formed of an integrated circuit (IC). The first source driving circuit 310 may be attached to a surface of the first source circuit board 210 in a chip on film (COF) method. The second source driving circuit 320 may be attached to a surface of the second source circuit board 220 in the COF method.

The control circuit board 400 may be electrically connected to the first source circuit board 210 and the second source circuit board 220. The control circuit board 400 may be attached to the first source circuit board 210 and the second source circuit board 220 using an anisotropic conductive film. The control circuit board 400 may be a printed circuit board.

A timing control circuit 401 may be formed of an integrated circuit. The timing control circuit 401 may be attached to a surface of the control circuit board 400.

The timing control circuit 401 may transmit digital video data to the first source driving circuit 310 and the second source driving circuit 320, and control driving timing of the first source driving circuit 310 and the second source driving circuit 320. For example, the timing control circuit 401 may transmit first digital video data and a first timing control signal to the first source driving circuit 310, and transmit second digital video data and a second timing control signal to the second source driving circuit 320.

Further, the timing control circuit 401 may be connected to power lines of the display panel 100 via the first source circuit board 210 or the second source circuit board 220, and the pads of the pad-region SBA.

A sensor control circuit 402 may be formed of an integrated circuit. The sensor control circuit 402 may be attached to a surface of the control circuit board 400. The sensor control circuit 402 may be connected to sensor electrodes via the control circuit board 400, the first source circuit board 210, the second source circuit board 220, and sensor fan-out lines and sensor lines of the display panel 100. In other embodiments, the sensor control circuit 420 may be disposed on a surface of a separate flexible circuit board. An end of the flexible circuit board may be connected to the display panel 100. The sensor control circuit 402 may be electrically connected to the sensor electrodes via the flexible circuit board, and the sensor fan-out lines and the sensor lines of the display panel 100.

The sensor control circuit 402 may apply a sensor driving signal to the sensor electrodes and sense a change amount of self-capacitance of each of the sensor electrodes. The sensor control circuit 402 may determine user's touch, user's approach, or the like according to the change amount of the self-capacitance of each of the sensor electrodes. The user's touch means that an object such as a user's finger or a pen may be in direct contact with a surface of the display panel 100. The user's approach means that the object such as the user's finger or the pen hovers over a surface of the display panel 100.

The first circuit board 610 and the second circuit board 620 may be electrically connected to the control circuit board 400. Each of the first circuit board 610 and the second circuit board 620 may be attached to the control circuit board 400 using an anisotropic conductive film. Each of the first circuit board 610 and the second circuit board 620 may be a flexible film such as a flexible printed circuit board, a printed circuit board, or a chip on film.

The first integrated circuit 710 may be attached to a surface of the first circuit board 610 in the COF method. The second integrated circuit 720 may be attached to a surface of the second circuit board 620 in the COF method. Accordingly, each of the first integrated circuit 710 and the second integrated circuit 720 may be electrically connected to the timing control circuit 401. At least one of the first integrated circuit 710 and the second integrated circuit 720 may transmit digital video data to the timing control circuit 401.

Each of the first roller 410 and the second roller 420 may extend in the second direction DR2. Further, each of the first roller 410 and the second roller 420 may move in the first direction DR1. In addition, each of the first roller 410 and the second roller 420 may have a rotation axis in the second direction DR2 and may rotate in a first rotation direction or a second rotation direction. The first rotation direction may be a counterclockwise direction, and the second rotation direction may be a clockwise direction. For example, each of the first roller 410 and the second roller 420 may move in the first direction DR1 and may rotate in the first rotation direction or the second rotation direction.

A first bending portion BA1 of the first auxiliary region AA1 may move in the first direction DR1 according to the movement and the rotation of the first roller 410. A second bending portion BA2 of the second auxiliary region AA2 may move in the first direction DR1 according to the movement and the rotation of the second roller 420.

In case that the first roller 410 moves to the right side while rotating in the second rotation direction, the first bending portion BA1 of the first auxiliary region AA1 may move to the left side. Accordingly, the first bending portion BA1 of the first auxiliary region AA1 may be disposed away from the main region MA. Therefore, the first auxiliary region AA1 may be widened when viewed from the front of the display device 10.

In case that the second roller 420 moves to the left side while rotating in the first rotation direction, the second bending portion BA2 of the second auxiliary region AA2 may move to the right side. Accordingly, the second bending portion BA2 of the second auxiliary region AA2 may be disposed away from the main region MA. Therefore, the second auxiliary region AA2 may be widened when viewed from the front of the display device 10.

For example, in case that the first roller 410 moves to the right side while rotating in the second rotation direction, and the second roller 420 moves to the left side while rotating in the first rotation direction, the display device 10 may be switched from a first state to a second state.

In contrast, in case that the first roller 410 moves to the left side while rotating in the first rotation direction, the first bending portion BA1 of the first auxiliary region AA1 may move to the right side. Accordingly, the first bending portion BA1 of the first auxiliary region AA1 may be disposed adjacent to the main region MA. Therefore, the first auxiliary region AA1 may be narrowed when viewed from the front of the display device 10.

In case that the second roller 420 moves to the right side while rotating in the second rotation direction, the second bending portion BA2 of the second auxiliary region AA2 may move to the left side. Accordingly, the second bending portion BA2 of the second auxiliary region AA2 may be disposed adjacent to the main region MA. Therefore, the second auxiliary region AA2 may be narrowed when viewed from the front of the display device 10.

For example, in case that the first roller 410 moves to the left side while rotating in the first rotation direction, and the second roller 420 moves to the right side while rotating in the second rotation direction, the display device 10 may be switched from the second state to the first state.

The first bending portion BA1 of the first auxiliary region AA1 in the first state of the display device 10 may be disposed closer to the main region MA than the first bending portion BA1 of the first auxiliary region AA1 in the second state of the display device 10. Therefore, in the second state of the display device 10, most of the first auxiliary region AA1 and the second auxiliary region AA2 may be visible from the front of the display device 10. In the first state of the display device 10, the first auxiliary region AA1 and the second auxiliary region AA2 may be hardly visible from the front of the display device 10. For example, in the first state of the display device 10, the first auxiliary region AA1 and the second auxiliary region AA2 may be visible from the right and left edges of the display device 10.

The length of the front surface of the display panel 100 in the first direction DR1 in the second state of the display device 10 may be longer than the length of the front surface of the display panel 100 in the first direction DR1 in the first state of the display device 10. Further, in the second state of the display device 10, the area of the first auxiliary region AA1 overlapping the main region MA in the third direction DR3 may be less than the area of the first auxiliary region AA1 not overlapping the main region MA in the third direction DR3. On the contrary, in the first state of the display device 10, the area of the first auxiliary region AA1 overlapping the main region MA in the third direction DR3 may be greater than the area of the first auxiliary region AA1 not overlapping the main region MA in the third direction DR3. Further, in the second state of the display device 10, the area of the second auxiliary region AA2 overlapping the main region MA in the third direction DR3 may be less than the area of the second auxiliary region AA2 not overlapping the main region MA in the third direction DR3. On the contrary, in the first state of the display device 10, the area of the second auxiliary region AA2 overlapping the main region MA in the third direction DR3 may be greater than the area of the second auxiliary region AA2 not overlapping the main region MA in the third direction DR3.

Since the first auxiliary region AA1 may be bent or curved as the first roller 410 rotates, the curvature of the first roller 410 and the curvature of the first auxiliary region AA1 may be substantially the same. Since the second auxiliary region AA2 may be bent or curved as the second roller 420 rotates, the curvature of the second roller 420 and the curvature of the second auxiliary region AA2 may be substantially the same. Further, since the curvature of the first roller 410 and the curvature of the second roller 420 may be substantially the same, the curvature of the first auxiliary region AA1 and the curvature of the second auxiliary region AA2 may be substantially the same. Furthermore, in order to prevent the pad-region SBA from interfering with the first and second auxiliary regions AA1 and AA2 in case that the pad-region SBA is bent, the curvature of the pad-region SBA may be different from the curvature of the first auxiliary region AA1 or the curvature of the second auxiliary region AA2. For example, the curvature of the pad-region SBA may be less than the curvature of the first auxiliary region AA1 and the curvature of the second auxiliary region AA2.

As shown in FIGS. 1A to 4, the first auxiliary region AA1 and the second auxiliary region AA2 may slidably move as the first roller 410 and the second roller 420 move, so that the size of the display panel 100, that is, the size of a display area, in which images may be displayed, viewed from the front of the display device 10 may be adjusted. Therefore, the user may select the size of the display panel 100 by controlling the display device 10 to be in the first state or the second state according to the intended use of the display device 10.

FIGS. 2A and 2B are schematic cross-sectional views of a display device according to an embodiment. As an example of the display device 10 taken along line A-A′ of FIG. 1A, FIG. 2A illustrates the display device 10 in which the bending region BD may be bent, and FIG. 2B illustrates the display device 10 in which the bending region BD may be unfolded.

Referring to FIGS. 2A and 2B, the display panel 100 may include a display layer 110, a lower film 1200 disposed on the display layer 110, an elastic member 300 disposed on the lower film 1200, and a support member 1400 disposed on the elastic member 300.

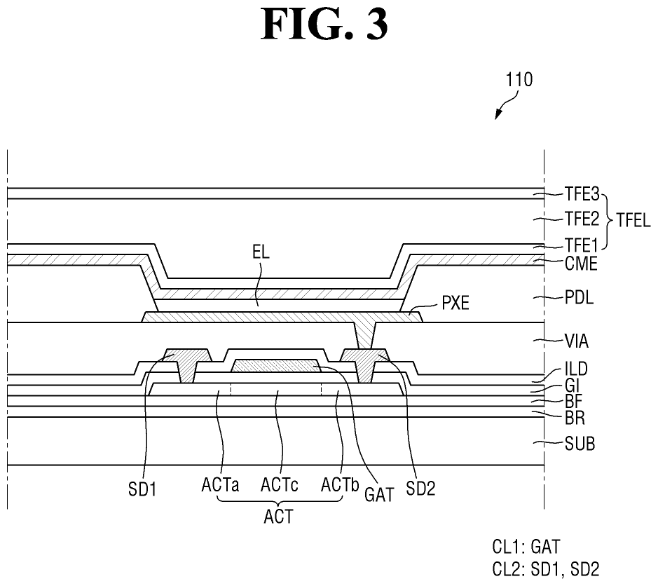

The display layer 110 may include a variety of conductive layers and a variety of insulating layers for displaying an image. The display layer 110 may include a first region including a display area, a second region spaced apart from the first region, and a third region between the first region and the second region, the third region being bent (see FIG. 2A). In an embodiment, the first region (e.g., display area) may correspond to the main region MA, the first auxiliary region AA1, and/or the second auxiliary region AA2, the second region may correspond to the pad region SR, and the third region may correspond to the bending region BD. The display layer 110 will be described later in detail with reference to FIG. 3.

The lower film 1200 may support the display layer 110. The lower film 1200 may be disposed over the entire area of the display panel 100 except for the bending region BD. For example, the lower film 1200 may not be disposed in the bending region BD. The lower film 1200 may include a first lower film 1210 disposed in the main region MA and the auxiliary region AA1/AA2, and a second lower film 1220 disposed in the pad-region SR.

The elastic member 300 may be disposed on the lower film 1200. Specifically, the elastic member 300 may be disposed on the first lower film 1210. For example, the elastic member 300 may be disposed in the main region MA and the auxiliary region AA1/AA2.

The elastic member 300 may alleviate stress applied to the display layer 110. In addition, the elastic member 300 may further serve to absorb an impact applied to the display layer 110.

The elastic member 300 may be made of a material having an elastic modulus. For example, the elastic member 300 may include polyurethane or the like, but is not limited thereto.

The elastic member 300 may slide along with the display layer 110 during the sliding operation of the auxiliary region AA1/AA2. In case that a part of the display layer 110 is bent during the sliding operation of the display device 10, the elastic member 300 may absorb stress occurring due to the bending to alleviate stress applied to the display layer 110.

The support member 1400 may overlap the main region MA and the auxiliary region AA1/AA2. The support member 1400 may include joint portions 1410 disposed in the auxiliary region AA1/AA2 and a flat plate portion 1420 disposed in the main region MA.

Each of the joint portions 1410 may have a shape extending in a second direction DR2. The joint portions 1410 may have the same shape and the same size, but are not limited thereto. The joint portions 1410 may be arranged in a first direction DR1. The adjacent joint portions 1410 may be spaced apart from each other by an interval. At the bending portion of the auxiliary region AA1/AA2, the interval between adjacent joint portions 1410 may be decreased.

The flat panel portion 1420 may support the elastic member 300, the first lower film 1210, and the display layer 110 disposed in the main region MA during the sliding operation of the display device 10.

The display panel 100 may further include a first adhesive member 510 disposed between the display layer 110 and the first lower film 1210, a second adhesive member 520 disposed between the display layer 110 and the second lower film 1220, a third adhesive member 530 disposed between the first lower film 1210 and the elastic member 300, and a fourth adhesive member 540 disposed between the elastic member 300 and the support member 1400. The first adhesive member 510 and the second adhesive member 520 may be direct1y disposed on the display layer 110 in common, but may have different thicknesses and physical properties. A description thereof will be given later.

A pad portion (not shown) may be provided at the end of the pad-region SR of the display panel 100. The second source circuit board 220 may be connected to the pad portion (not shown). The second source circuit board 220 may be disposed on another side surface of the pad-region SR of the display panel 100 in a third direction DR3. The second source circuit board 220 may be a flexible circuit board or a film.

FIG. 3 is a schematic cross-sectional view of a pixel of a display device according to an embodiment.

Referring to FIG. 3, the display layer 110 may include a base substrate SUB, a barrier layer BR, a buffer layer BF, a semiconductor layer ACT, a gate insulating layer GI, a first conductive layer CL1, an interlayer insulating layer ILD, a second conductive layer CL2, a via layer VIA, a pixel electrode PXE, and a pixel defining layer PDL. Each of the layers described above may consist of a single layer, or a stack of multiple layers. Another layer may be further disposed between the respective layers.

The base substrate SUB may support the respective layers disposed thereon. The base substrate SUB may be made of, e.g., an insulating material such as a polymer resin, but is not limited thereto and the base substrate SUB may include a metal material.

The barrier layer BR may be disposed on the base substrate SUB. The barrier layer BR may prevent diffusion of impurity ions, prevent permeation of moisture or external air, and perform a surface planarization function. The barrier layer BR may include silicon nitride, silicon oxide, silicon oxynitride, or the like, or a combination thereof. The barrier layer BR may be omitted depending on the type of the base substrate SUB, process conditions, and the like.

The buffer layer BF may be disposed on the barrier layer BR. The buffer layer BF may include at least one of silicon nitride, silicon oxide, and silicon oxynitride. The buffer layer BF may be omitted depending on the type of the base substrate SUB, process conditions, and the like.

The semiconductor layer ACT may be disposed on the buffer layer BF. The semiconductor layer ACT may be made of polycrystalline silicon, monocrystalline silicon, amorphous silicon, or the like.

The semiconductor layer ACT may include a channel region ACTc that overlaps a gate electrode GAT disposed thereabove in the thickness direction, and a first source/drain region ACTa and a second source/drain region ACTb that may be respectively located on a side and another side of the channel region ACTc. The first and second source/drain regions ACTa and ACTb of the semiconductor layer ACT may include carrier ions, thereby having higher conductivity and lower electric resistance than the channel region ACTc.

A gate insulating layer GI may be disposed on the semiconductor layer ACT. The gate insulating layer GI may not only cover the top surface of the semiconductor layer ACT except for the portion where a contact hole may be formed, but may also cover the side surface of the semiconductor layer ACT. The gate insulating layer GI may be disposed substantially over the entire surface of the base substrate SUB. The gate insulating layer GI may include a silicon compound, a metal oxide, or the like, or a combination thereof.

The first conductive layer CL1 may be disposed on the gate insulating layer GI. The first conductive layer CL1 may be a gate conductive layer, and may include the gate electrode GAT.

The interlayer insulating layer ILD may be disposed on the first conductive layer CL1. The interlayer insulating layer ILD may be substantially disposed over the entire surface of the gate insulating layer GI.

The second conductive layer CL2 may be disposed on the interlayer insulating layer ILD. The second conductive layer CL2 may be a data conductive layer, and may include a first source/drain electrode SD1 and a second source/drain electrode SD2 of a transistor. The first source/drain electrode SD1 may be connected to the first source/drain region ACTa of the semiconductor layer ACT through a contact hole penetrating the gate insulating layer GI and the interlayer insulating layer ILD. The second source/drain electrode SD2 may be connected to the second source/drain region ACTb of the semiconductor layer ACT through a contact hole penetrating the gate insulating layer GI and the interlayer insulating layer ILD.

The via layer VIA may be disposed on the second conductive layer CL2. The via layer VIA may include an inorganic insulating material or an organic insulating material. The via layer VIA may be a single layer or a multilayer stack of different materials.

The via layer VIA may be disposed on top of the interlayer insulating layer ILD to completely cover the top surface of the interlayer insulating layer ILD. In case that the via layer VIA is formed of an organic layer, the top surface thereof may be flat despite a lower stepped portion.

The pixel electrode PXE may be disposed on the via layer VIA. The pixel electrode PXE may be an anode electrode. The pixel electrode PXE may be separately disposed for each pixel. The pixel electrode PXE may be electrically connected to the second source/drain electrode SD2 through a contact hole penetrating the via layer VIA.

The pixel defining layer PDL may be disposed on the pixel electrode PXE. The pixel defining layer PDL may include an opening partially exposing the pixel electrode PXE. The pixel defining layer PDL may be formed of an organic insulating material or an inorganic insulating material.

The light emitting layer EL may be disposed on the pixel electrode PXE exposed by the pixel defining layer PDL. The light emitting layer EL may include an organic material layer. The light emitting layer EL may further include a hole injection/transport layer and/or an electron injection/transport layer.

The common electrode CME may be disposed on the light emitting layer EL. The common electrode CME may be extended across all the pixels. The common electrode CME may be a cathode electrode. The pixel electrode PXE, the light emitting layer EL, and the common electrode CME may constitute an organic light emitting element.

The pixel electrode PXE, the light emitting layer EL, and the common electrode CME may constitute an organic light emitting element.

A thin film encapsulation layer TFEL including a first inorganic film TFE1, a first organic film TFE2, and a second inorganic film TFE3 may be disposed on top of the common electrode CME. Although not shown, the first inorganic film TFE1 and the second inorganic film TFE3 may be in contact with each other at the end of the thin film encapsulation layer TFEL. The first organic film TFE2 may be sealed by the first inorganic film TFE1 and the second inorganic film TFE3.

The pixels of the display panel 100, whose structure has been described above with reference to FIG. 3, may be disposed in the auxiliary region AA1/AA2 of the display device 10. The auxiliary region AA1/AA2 may be partially out-folded in case that the display device 10 slides. Tensile stress may be applied to the variety of insulating layers included in the display panel 100. In case that excessive tensile stress is applied, a crack may occur in the insulating layer, which may result in a defect in the display device 10. For example, in case that the display device 10 is partially out-folded by sliding, tensile stress may be applied to the first inorganic layer TFE1 and the second inorganic layer TFE3 included in the thin film encapsulation layer TFEL in the pixel structure. In case that excessive tensile stress is applied, a crack may occur, and thus the function of encapsulating the light emitting element may be deteriorated.

Hereinafter, the first and second adhesive members 510 and 520 used to attach the lower film 1200 to the display layer 110 will be described. Specifically, structures and physical properties of the first adhesive member 510, which may be located in the main region MA and may be capable of decreasing the tensile stress applied to the display layer 110 during out-folding, and the second adhesive member 520, which may be located in the pad-region SR and may be capable of preventing the alignment defect in an attachment step of the second source circuit board 220, will be described.

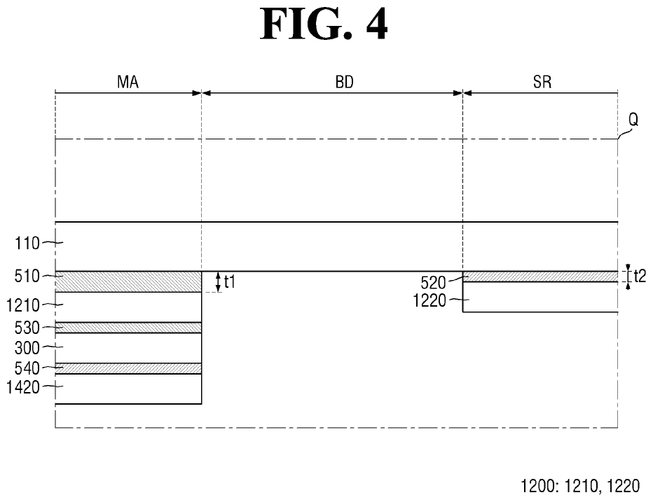

FIG. 4 is an enlarged schematic view of region Q of FIG. 2B. For example, FIG. 4 is a development view of the bending region BD of the display panel 100 in a flat unfolded state.

Referring to FIG. 4, the lower film 1200, the elastic member 300, and the support member 1400 may be disposed on a surface of the display layer 110.

As described above, the lower film 1200 may include the first lower film 1210 disposed in the main region MA and the second lower film 1220 disposed in the pad-region SR. The first lower film 1210 and the second lower film 1220 may be made of substantially the same material. The lower film 1200 may be fabricated by disposing a film layer and then removing a portion disposed in the bending region BD by a punching step, but is not limited thereto.

The first adhesive member 510 may be disposed between the display layer 110 and the first lower film 1210. The first adhesive member 510 may attach the display layer 110 and the first lower film 1210 to each other. The first adhesive member 510 may have a first thickness t1. The first adhesive member 510 may have a first storage modulus. The first storage modulus may be about 200 kPa or less, or about 100 kPa or less.

In case that the first storage modulus of the first adhesive member 510 is relatively small, there may be a sufficient layer separation between the display layer 110 and the first lower film 1210 that may be attached to each other via the adhesive member 510, and in the corresponding region, the neutral plane of the display layer 110 may move away therefrom toward the first lower film 1210. The neutral plane may indicate a plane connecting points of zero stress. Through this, it may be possible to decrease the tensile stress applied to the display layer 110 in the out-folding performed in case that the display device 10 slides. For example, in case that the first storage modulus of the first adhesive member 510 is relatively small, the tensile stress applied to the display layer 110 during the out-folding may be decreased, thereby minimizing the occurrence of a crack that may occur in the variety of insulating layers included in the display layer 110.

The second adhesive member 520 may be disposed between the display layer 110 and the second lower film 1220. The second adhesive member 520 may attach the display layer 110 and the second lower film 1220 to each other. The second adhesive member 520 may have a second thickness t2 less than the first thickness t1. The second adhesive member 520 may overlap the main region MA. The second adhesive member 520 may partially overlap the second source circuit board 220.

The second adhesive member 520 may have a second storage modulus greater than the first storage modulus of the first adhesive member 510. The second storage modulus may be greater than or equal to about 500 kPa. The second adhesive member 520 may contain the same material as the first adhesive member 510 even if its storage modulus may be different from that of the first adhesive member 510.

The second adhesive member 520 may receive heat and pressure in the thickness direction in the attachment step of the second source circuit board 220. In order to prevent occurrence of an alignment error, it may be advantageous that the second thickness t2 may be relatively small and the second storage modulus may be relatively large. For example, as the second thickness t2 of the second adhesive member 520 decreases and the second storage modulus thereof increases, the change in alignment between the display layer 110 and the second lower film 1220 may be minimized, thereby reducing the defect in which the relative positions may be changed. Further, the second adhesive member 520 may have excellent durability against hot pressing.

The first adhesive member 510 and the second adhesive member 520 may contain the same material. The first adhesive member 510 and the second adhesive member 520 may contain at least one of acryl and silicon. For example, the first adhesive member 510 and the second adhesive member 520 may contain the same material, but may have different thicknesses t1 and t2 and different physical properties such as a storage modulus. However, the disclosure is not limited thereto, and the first adhesive member 510 and the second adhesive member 520 may contain different materials.

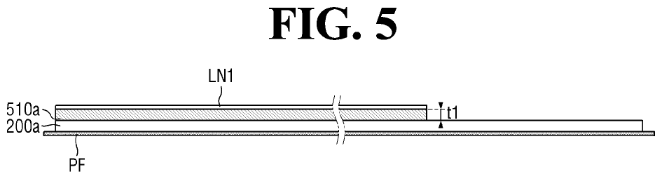

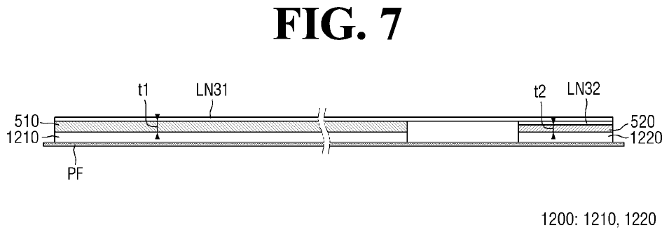

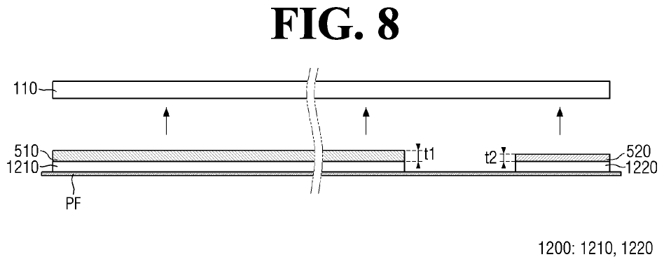

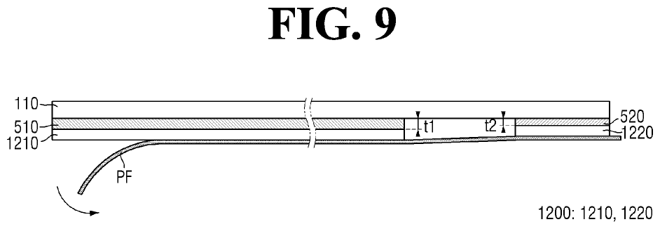

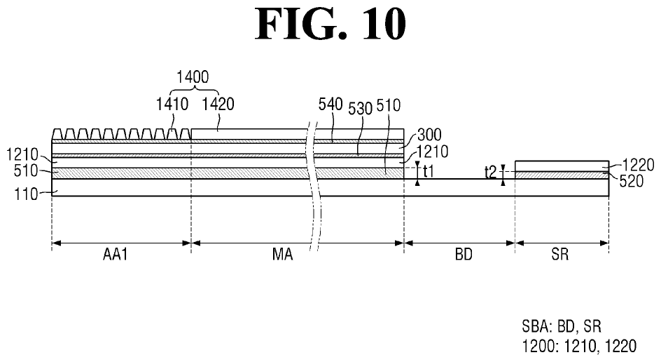

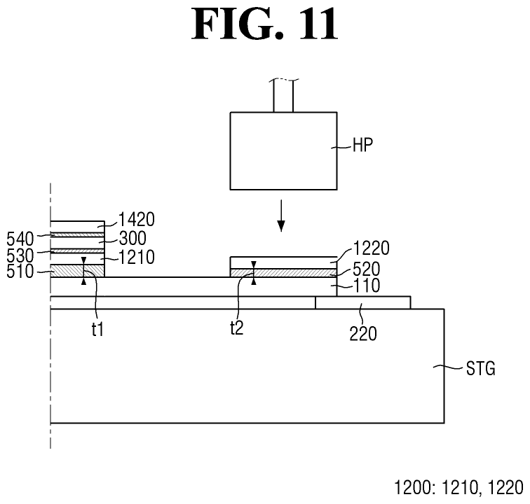

FIGS. 5 to 11 are schematic views illustrating a manufacturing process of a display device according to an embodiment. Specifically, FIGS. 5 to 11 are schematic views illustrating a manufacturing process of the first adhesive member 510 and the second adhesive member 520 shown in FIGS. 2A, 2B, and 4.

Referring to FIGS. 5 to 11, first, a lower film member 200a attached with a protection film PF may be prepared. A first adhesive material 510a may be coated to have the first thickness t1 on a surface of the lower film member 200a, which may be opposite to the surface where the protection film PF may be attached, and a first liner LN1 may be disposed on the first adhesive material 510a. The first adhesive material 510a may be coated only on a part of the lower film member 200a. The first adhesive material 510a may have the first storage modulus. The first adhesive material 510a may be changed into the first adhesive member 510 described above with reference to FIGS. 2A, 2B, and 4 through a subsequent step.

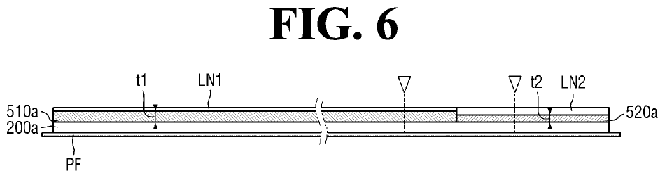

Second, a second adhesive material 520a may be coated on an area of the lower film member 200a where the first adhesive material 510a has not been coated. The second adhesive material 520a may be coated to have the second thickness t2 less than the first thickness t1, and a second liner LN2 may be disposed on the second adhesive material 520a. The second liner LN2 may have a thickness greater than the thickness of the first liner LN1. Accordingly, the top surface of the first liner LN1 and the top surface of the second liner LN2 may be substantially aligned so that a stepped portion may not be formed. The second adhesive material 520a may have the second storage modulus greater than the first storage modulus. The second adhesive material 520a may be changed into the second adhesive member 520 described above with reference to FIGS. 2A, 2B, and 4 through a subsequent step. Although FIG. 6 illustrates that the end of the first adhesive material 510a and the end of the second adhesive material 520a may be in contact with each other in the horizontal direction, the first adhesive material 510a and the second adhesive material 520a may partially overlap in the area where they meet each other in the thickness direction.

Third, the area where the first adhesive material 510a and the second adhesive material 520a meet may be partially punched and removed to form the first adhesive member 510 and the second adhesive member 520. The corresponding region may correspond to the bending region BD of the display panel 100 through a subsequent step. In this punching step, the lower film member 200a may also be punched and changed into the lower film 1200 included in the display panel according to an embodiment.

A third-first liner LN31 may be disposed on the first adhesive member 510 and the second adhesive member 520. After the punching step, due to the difference between thicknesses t1 and t2 of the first adhesive member 510 and the second adhesive member 520, a stepped portion may be formed between the top surface of the first adhesive member 510 and the top surface of the second adhesive member 520. Accordingly, a third-second liner LN32 may be further disposed between the third-first liner LN31 and the second adhesive member 520 to compensate for the stepped portion. Although not shown, an adhesive material may be further disposed between the third-first liner LN31 and the third-second liner LN32. The third-second liner LN32 may have a thickness substantially the same as the difference between the first thickness t1 and the second thickness t2.

Fourth, the lower film 1200 may be attached onto the display layer 110. Specifically, the first lower film 1210 may be attached onto the display layer 110 via the first adhesive member 510, and the second lower film 1220 may be attached onto the display layer 110 via the second adhesive member 520. The region where the first lower film 1210 may be attached may become the main region MA of the display panel 100 through a subsequent step, and the region where the second lower film 1220 may be attached may become the pad-region SR of the display panel 100 through the subsequent step.

Fifth, the protection film PF may be removed, and the elastic member 300 and the support member 1400 may be disposed on the first lower film 1210. The third adhesive member 530 may be disposed between the first lower film 1210 and the elastic member 300, and the fourth adhesive member 540 may be disposed between the elastic member 300 and the support member 1400. The region where the joint portion 1410 of the support member 1400 may be disposed may be the auxiliary region AA1/AA2, and the region where the flat plate portion 1420 may be disposed may be the main region MA.

Sixth, the second source circuit board 220 may be attached onto a surface of the display layer 110. The attachment step of the second source circuit board 220 may be a thermo-compression bonding step using a thermo-compression bonding device HP and a stage STG. Specifically, the thermo-compression bonding step may be conducted by disposing the second source circuit board 220 on a surface opposite to the surface of the display layer 110, on which the second adhesive member 520 may be disposed, and then applying heat toward the display layer 110 to heat the second lower film 1220 using the thermo-compression bonding device HP. Since the second thickness t2 of the second adhesive member 520, which may be disposed between the display layer 110 and the second lower film 1220, may be less than the first thickness t1 of the first adhesive member 510, and the second storage modulus may be greater than the first storage modulus, it may be possible to prevent the occurrence of the alignment error between the second lower film 1220 and the display layer 110.

The display device 10 according to an embodiment may include the first adhesive member 510 disposed between the display layer 110 and the first lower film 1210 in the main region MA and having the first thickness t1, and the second adhesive member 520 disposed between the display layer 110 and the second lower film 1220 in the pad-region SR and having the second thickness t2 that may be less than the first thickness t1. Further, the first storage modulus of the first adhesive member 510 may be less than the second storage modulus of the second adhesive member 520.

For example, in the display device 10 according to an embodiment, the first adhesive member 510 and the second adhesive member 520 may be formed to have different thicknesses t1 and t2, and different physical properties such as the storage modulus according to the arrangement positions thereof. Accordingly, it may be possible to decrease the tensile stress applied to the variety of insulating layers included in the display layer 110 during the sliding operation of the display device 10, thereby preventing the occurrence of a crack and defect of the display device 10 due to the crack.

Hereinafter, another embodiment of the display device 10 will be described. In the following description of the display device according to another embodiment, redundant parts of the description of the display device 10 according to an embodiment will be omitted, and differences will be described.

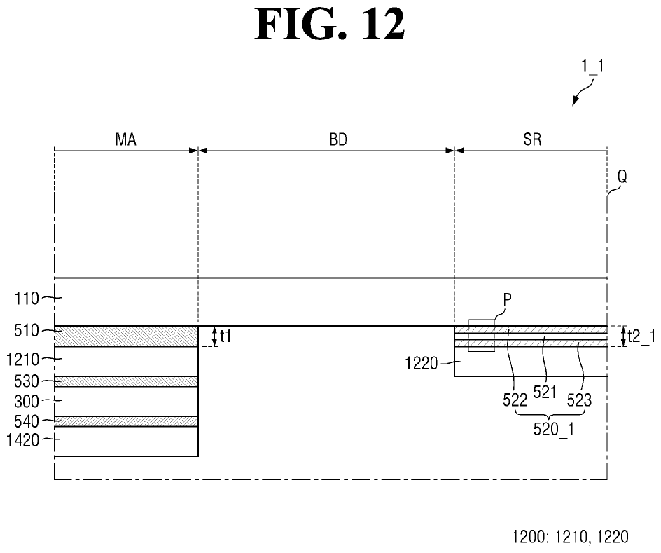

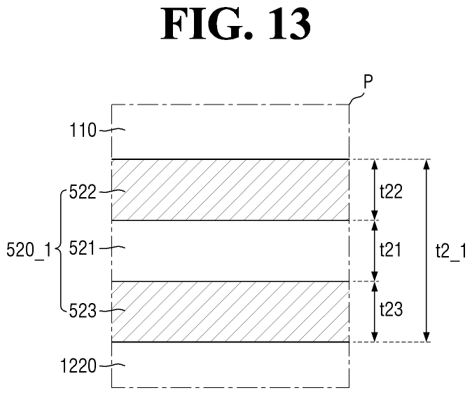

FIG. 12 is a schematic diagram illustrating a part of a display device according to another embodiment. FIG. 13 is an enlarged schematic view of region P of FIG. 12. Specifically, FIG. 12 is an enlarged schematic view of a region corresponding to region Q of FIG. 2B in a display device according to another embodiment.

Referring to FIGS. 12 and 13, the display device according to an embodiment may be different from the display device according to another embodiment in that it may include a second adhesive member 520_1 having a different structure.

In an embodiment, the second adhesive member 520_1 may be disposed in the pad-region SR. The second adhesive member 520_1 may be disposed between the display layer 110 and the second lower film 1220.

The second adhesive member 520_1 may include a base film 521, a first sub-adhesive layer 522 disposed on a surface of the base film 521, and a second sub-adhesive layer 523 disposed on another surface opposite to the surface of the base film 521. For example, the first sub-adhesive layer 522 and the second sub-adhesive layer 523 may be disposed to be opposite to each other with the base film 521 interposed therebetween.

The base film 521 may contain a flexible polymer material such as polyimide. The first sub-adhesive layer 522 and the second sub-adhesive layer 523 may contain the same material as the second adhesive member 520 included in the display device 10 according to an embodiment. The first sub-adhesive layer 522 and the second sub-adhesive layer 523 may have the same storage modulus. In addition, the storage modulus of the first sub-adhesive layer 522 and the second sub-adhesive layer 523 may be the same as the second storage modulus of the second adhesive member 520 included in the display device 10 according to an embodiment. For example, the storage modulus of the first sub-adhesive layer 522 and the storage modulus of the second sub-adhesive layer 523 may be greater than the first storage modulus of the first adhesive member 510.

In an embodiment, a second thickness t2_1 of the second adhesive member 520_1 may be equal to the sum of a thickness t21 of the base film 521, a thickness t22 of the first sub-adhesive layer 522, and a thickness t23 of the second sub-adhesive layer 523. The thickness t22 of the first sub-adhesive layer 522 may be less than the first thickness t1 of the first adhesive member 510, and the thickness t23 of the second sub-adhesive layer 523 may also be less than the first thickness t1 of the first adhesive member 510. Further, the sum of the thickness t22 of the first sub-adhesive layer 522 and the thickness t23 of the second sub-adhesive layer 523 may be less than the first thickness t1 of the first adhesive member 510. However, the first thickness t1 of the first adhesive member 510 may be substantially the same as the second thickness t2_1 of the second adhesive member 520_1. Through this, in the step of attaching the lower film 1200 onto the display layer, the attachment position of the lower film 1200 may be more precisely controlled.

In this embodiment, in the second adhesive member 520_1, the sum of the thickness t22 and the thickness t23 of the first sub-adhesive layer 522 and the second sub-adhesive layer 523 containing an adhesive material may be less than the first thickness t1 of the first adhesive member 510 due to the base film 521 disposed between the first sub-adhesive layer 522 and the second sub-adhesive layer 523. Accordingly, it may be possible to prevent the alignment defect in the attachment step of the second source circuit board 220.

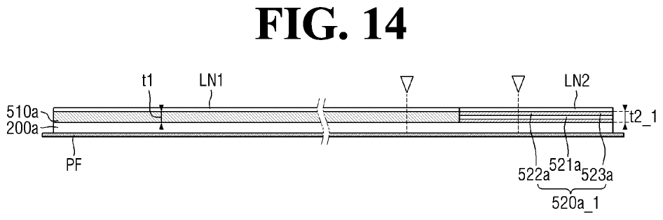

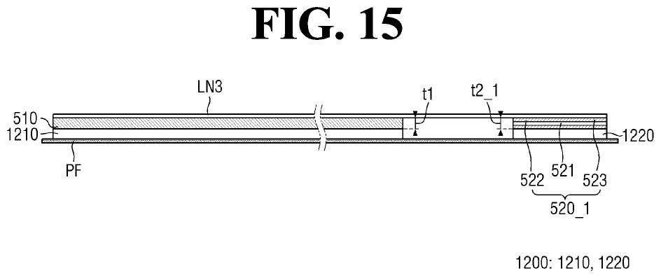

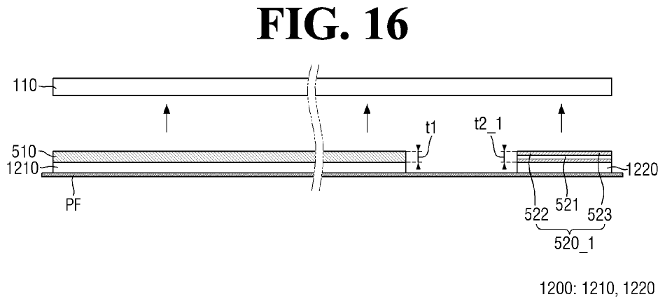

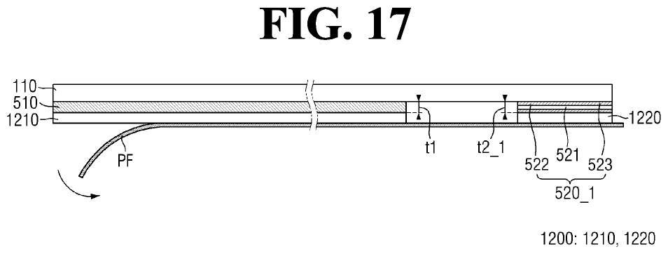

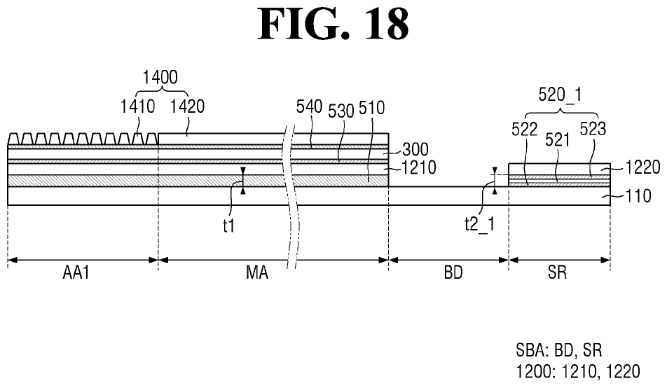

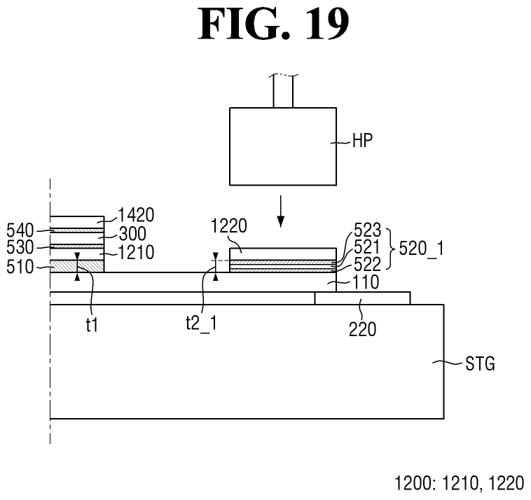

FIGS. 14 to 19 are schematic diagrams illustrating a manufacturing process of a display device according to another embodiment.

Referring to FIGS. 5, and 14 to 19, first, the lower film member 200a attached with the protection film PF may be prepared. The first adhesive material 510a may be coated to have the first thickness t1 on the surface of the lower film member 200a, which may be opposite to the surface where the protection film PF may be attached, and the first liner LN1 may be disposed on the first adhesive material 510a. The first adhesive material 510a may be coated only on a part of the lower film member 200a. The first adhesive material 510a may have the first storage modulus.

Second, a second adhesive material 520a 1 may be coated on an area of the lower film member 200a where the first adhesive material 510a has not been coated. The second adhesive material 520a_1 may be coated to have the second thickness t2_1 the same as the first thickness t1, and the second liner LN2 may be disposed on the second adhesive material 520a_1.

The second adhesive material 520a_1 may include a base film portion 521a, a first sub-adhesive material 522a disposed on a surface of the base film portion 521a, and a second sub-adhesive material 523a disposed on another surface opposite to the surface of the base film portion 521a.

The first sub-adhesive material 522a and the second sub-adhesive material 523a may have a storage modulus greater than the storage modulus of the first adhesive material 510a. The second adhesive material 520a_1 may be changed into the second adhesive member 520_1 described above with reference to FIGS. 12 and 13 through a subsequent step. Although FIG. 14 illustrates that the end of the first adhesive material 510a and the end of the second adhesive material 520a 1 may be in contact with each other in the horizontal direction, the first adhesive material 510a and the second adhesive material 520a_1 may partially overlap in the area where they meet each other in the thickness direction.

Third, the area where the first adhesive material 510a and the second adhesive material 520a_1 meet may be partially punched and removed to form the first adhesive member 510 and the second adhesive member 520_1. Further, the third liner LN3 may be disposed on the first adhesive member 510 and the second adhesive member 520_1. The corresponding region may correspond to the bending region BD of the display panel through a subsequent step. In this punching step, the lower film member 200a may also be punched and changed into the lower film 1200 included in the display panel 100 according to an embodiment.

Fourth, the lower film 1200 may be attached onto the display layer 110. Specifically, the first lower film 1210 may be attached onto the display layer 110 via the first adhesive member 510, and the second lower film 1220 may be attached onto the display layer 110 via the second adhesive member 520_1. The region where the first lower film 1210 has been attached may become the main region MA of the display panel 100 through a subsequent step, and the area where the second lower film 1220 has been attached may become the pad-region SR of the display panel 100 through the subsequent step.

Fifth, the protection film PF may be removed, and the elastic member 300 and the support member 1400 may be disposed on the first lower film 1210. The third adhesive member 530 may be disposed between the first lower film 1210 and the elastic member 300, and the fourth adhesive member 540 may be disposed between the elastic member 300 and the support member 1400. The region where the joint portion 1410 of the support member 1400 may be disposed may be the auxiliary region AA1/AA2, and the region where the flat plate portion 1420 may be disposed may be the main region MA.

Sixth, the second source circuit board 220 may be attached onto a surface of the display layer 110. The attachment step of the second source circuit board 220 may be the thermo-compression bonding step using the thermo-compression bonding device HP. Specifically, the thermo-compression bonding step may be conducted by disposing the second source circuit board 220 on the surface opposite to the surface of the display layer 110, on which the second adhesive member 520_1 may be disposed, and then applying heat toward the display layer 110 to heat the second lower film 1220 using the thermo-compression bonding device HP. In the second adhesive member 520_1 disposed between the display layer 110 and the second lower film 1220, the sum of the thickness t22 and the thickness t23 of the first-sub adhesive layer 522 and the second-sub adhesive layer 523, which may be made of an adhesive material, may be less than the first thickness t1 of the first adhesive member 510, and the second storage modulus of the first-sub adhesive layer 522 and the second-sub adhesive layer 523 may be greater than the first storage modulus of the first adhesive member 510. Therefore, it may be possible to prevent the occurrence of the alignment error between the second lower film 1220 and the display layer 110.

The display device 1_1 according to an embodiment may include the first adhesive member 510 disposed between the display layer 110 and the first lower film 1210 in the main region MA and having the first thickness t1, and the second adhesive member 520_1 disposed between the display layer 110 and the second lower film 1220 in the pad-region SR and having the second thickness t2_1 that may be less than the first thickness t1. Further, the storage modulus of the first sub-adhesive layer 522 and the second sub-adhesive layer 523 included in the second adhesive member 520_1 may be greater than the first storage modulus of the first adhesive member 510.

For example, in the display device 1_1 according to an embodiment, the adhesive materials may be formed to have different thicknesses and different physical properties such as the storage modulus according to the arrangement positions thereof. Accordingly, it may be possible to decrease the tensile stress applied to the variety of insulating layers included in the display layer 110 during the sliding operation of the display device 1_1, thereby preventing the occurrence of a crack and the defect of the display device 1_1 due to the crack.

Further, by having the first thickness t1 of the first adhesive member 510 and the second thickness t2_1 of the second adhesive member 520_1 which are the same, it may be possible to precisely control the attachment position of the lower film 1200 in the step of attaching the lower film 1200 onto the display layer during the manufacturing process of the display device 1_1.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a display layer including:
a first region including a display area;
a second region spaced apart from the first region in a first direction; and
a third region between the first region and the second region, the third region being bent;
a first lower film disposed on a bottom surface of the display layer and overlapping the first region in a plan view;
a second lower film disposed on the bottom surface of the display layer, overlapping the second region in a plan view, and spaced apart from the first lower film;
a first adhesive member disposed between the display layer and the first lower film and having a first thickness; and
a second adhesive member disposed between the display layer and the second lower film and having a second thickness smaller than the first thickness.

2. The display device of claim 1, wherein a storage modulus of the first adhesive member is smaller than a storage modulus of the second adhesive member.

3. The display device of claim 2, wherein the first adhesive member and the second adhesive member include a same material.

4. The display device of claim 1, wherein the first lower film and the second lower film include a same material.

5. The display device of claim 1, wherein
the display layer further includes an auxiliary region extending from a first side of the first region in a second direction intersecting the first direction,
the display device further includes a roller surrounded by at least a part of the auxiliary region,
a position of a bending portion of the auxiliary region is moved in the second direction by movement of the roller,
in a first state, the auxiliary region overlaps the first region in a plan view, and
in a second state, the auxiliary region does not overlap the first region in a plan view.

6. The display device of claim 5, further comprising:
a support member disposed on the bottom surface of the display layer,
wherein the support member includes:
a joint portion overlapping the auxiliary region in a plan view; and
a flat plate portion overlapping the first region in a plan view.

7. The display device of claim 5, wherein the first region overlaps the second adhesive member in a plan view.

8. The display device of claim 1, further comprising:
a printed circuit board disposed on a top surface of the display layer and overlapping the second region in a plan view, wherein
the printed circuit board partially overlaps the second adhesive member in a plan view.

9. A display device comprising:
a display layer including:
a first region including a display area;
a second region spaced apart from the first region in a first direction; and
a third region between the first region and the second region, the third region being bent;
a first lower film disposed on a bottom surface of the display layer and overlapping the first region in a plan view;
a second lower film disposed on the bottom surface of the display layer, overlapping the second region in a plan view, and spaced apart from the first lower film;
a first adhesive member disposed between the display layer and the first lower film; and
a second adhesive member disposed between the display layer and the second lower film,
wherein the second adhesive member includes:
a base film;
a first sub-adhesive layer disposed between the base film and the second region; and
a second sub-adhesive layer disposed between the base film and the second lower film.

10. The display device of claim 9, wherein
the first adhesive member has a first thickness, and
the first thickness is greater than a thickness of the first sub-adhesive layer and is greater than a thickness of the second sub-adhesive layer.

11. The display device of claim 10, wherein the first thickness is greater than a sum of a thickness of the first sub-adhesive layer and a thickness of the second sub-adhesive layer.

12. The display device of claim 9, wherein a storage modulus of the first adhesive member is smaller than at least one of a storage modulus of the first sub-adhesive layer and a storage modulus of the second sub-adhesive layer.

13. The display device of claim 12, wherein the storage modulus of the first sub-adhesive layer and the storage modulus of the second sub-adhesive layer are equal to each other.

14. The display device of claim 13, wherein the first adhesive member, the first sub-adhesive layer, and the second sub-adhesive layer include a same material.

15. The display device of claim 12, wherein
the first adhesive member has a first thickness, and
the second adhesive member has a second thickness equal to the first thickness.

16. The display device of claim 9, wherein the first lower film and the second lower film include a same material.

17. The display device of claim 9, wherein
the display layer further includes an auxiliary region extending from a first side of the first region in a second direction intersecting the first direction,
the display device further includes a roller surrounded by at least a part of the auxiliary region,
a position of a bending portion of the auxiliary region is moved in the second direction by movement of the roller,
in a first state, the auxiliary region overlaps the first region in a plan view, and
in a second state, the auxiliary region does not overlap the first region in a plan view.

18. The display device of claim 17, further comprising:
a support member disposed on the bottom surface of the display layer,
wherein the support member includes:
a joint portion overlapping the auxiliary region in a plan view; and
a flat plate portion overlapping the first region in a plan view.

19. The display device of claim 17, wherein the first region overlaps the second adhesive member in a plan view.

20. The display device of claim 9, further comprising:
a printed circuit board disposed on a top surface of the display layer and overlapping the second region in a plan view,
wherein the printed circuit board partially overlaps the second adhesive member in a plan view.
